(19) United States
(12) Patent Application Publication
(10) Pub. No.: US 2007/0082456 A1
(43) Pub. Date: Apr. 12, 2007

(54) Polishing composition and polishing method

(76) Inventors: Nobuo Uotani, Nagano (JP); Hiroshi Takahashi, Nagano (JP); Takashi Sato, Nagano (JP); Hajime Sato, Nagano (JP)

Correspondence Address: SUGHRUE MION, PLLC, 2100 PENNSYLVANIA AVENUE, N.W., SUITE 800, WASHINGTON, DC, 20037, US

(21) Appl. No.: 10/579,406

(22) PCT Filed: Nov. 15, 2004
(86) PCT No.: PCT/JP04/17318

§ 371 Date: May 15, 2006

Related U.S. Application Data
(60) Provisional application No. 60/523,684, filed on Nov. 21, 2003.
(60) Provisional application No. 60/526,263, filed on Dec. 3, 2003.
(60) Provisional application No. 60/571,525, filed on May 17, 2004.

(30) Foreign Application Priority Data
Nov. 14, 2003 (JP) 2003-385253
Nov. 25, 2003 (JP) 2003-394081
Nov. 28, 2003 (JP) 2003-398523
Apr. 30, 2004 (JP) 2004-135358

(51) Int. Cl. H01L 21/76

(52) U.S. Cl. 438/427

(57) ABSTRACT

To provide a polishing composition which allows high-speed polishing while etching and erosion are prevented and the flatness of metal film is maintained, there is provided a a polishing composition, comprising (A) a compound having three or more azole moieties, (B) an oxidizing agent, and (C) one or more species selected from among an amino acid, an organic acid, and an inorganic acid.

### CROSS REFERENCE TO RELATED APPLICATION

This application is an application filed under 35 U.S.C. §111(a) claiming benefit pursuant to 35 U.S.C. §119(e)(1) of the filing date of the Provisional Application No. 60/523,684 filed on Nov. 21, 2003, the filing date of the Provisional Application No.60/526,263 filed on Dec. 3, 2004, and the filing date of the Provisional Application No.60/571,525 filed on May 17, 2004, pursuant to 35 U.S.C. §111(b).

### TECHNICAL FIELD

The present invention relates to a polishing composition for use in polishing a substrate, and more particularly, to a polishing composition for polishing a metallic substrate. The invention also relates to a polishing method, and to a method for producing a substrate.

### BACKGROUND ART

Technical developments in ICs (integrated circuits) and LSI (large scale integration) have attained improvements in operation speed and degree of integration of these devices. For example, the performance of micro-processors and the capacity of memory chips have recently seen rapid improvements. Such improvements in device performance have in large measure been attained by virtue of development of micro-processing techniques. One typical example of micro-processing techniques is a chemical mechanical polishing method, which is a type of planarization technique. Chemical mechanical polishing is employed in planarization of an inter layer dielectric, a metal plug, and a metal wiring during a multi-layer wiring step.

Among these multi-wiring elements, in recent years, a metal wiring made of copper or copper alloy has been employed so as to prevent problematic delay of signals. Such copper or copper alloy wiring is fabricated by forming trenches in an inter layer dielectric in advance; if required, forming a thin barrier film formed of tantalum or tantalum nitride atop the trenches; and depositing copper or copper alloy through a technique such as the damascene method. During the above fabrication, excess copper or copper alloy remains on the inter layer dielectric. Thus, the wiring is formed while the excess copper or copper alloy is removed through polishing for planarization.

Meanwhile, a magnetic random access memory (MRAM) is one example of the magnetic recording media of interest. Regarding MRAM, there has been known a method for recording information to a specific bit in an element array. In the method, a bit-writing-in line and a word-writing-in line which cross each other while extending in the lengthwise and widthwise directions of an array, respectively, are provided, and information is written exclusively in an element located in the region where the two lines cross (see, for example, Japanese Patent Application Laid-Open (kokai) No. 10-116490). The metal wiring formed in the MRAM includes a conductor layer composed of aluminum or aluminum alloy, and copper or copper alloy; a ferromagnetic layer composed of nickel-iron (permalloy) and covering the conductor layer; and, if needed, a barrier film composed of a certain material (e.g., tantalum or tantalum nitride) and formed on the ferromagnetic layer. The metal wiring is formed through the damascene method, and excess portions of the conductor layer, the ferromagnetic layer, and the barrier film are removed through polishing performed in parallel, thereby providing a plane surface.

One possible approach for planarization with polishing is treatment by use of an abrasive containing abrasive. However, when the treatment is performed only by use of an abrasive, copper or copper alloy tends to be scratched due to moderate hardness thereof, considerably reducing yield of the device. Another possible approach is use of an abrasive containing an etchant, which is capable of dissolving copper. However, if this approach is employed, trenches as well as protruded portions are etched, thereby causing dishing (i.e., a plane surface cannot be provided, and a-portion of metal wiring is polished out).

Japanese Patent Application Laid-Open (kokai) No. 8-83780 discloses a metal-polishing composition for polishing a metal film composed of copper or copper alloy with preventing occurrence of the above phenomenon. The composition contains hydrogen peroxide, benzotriazole, and aminoacetic acid, and if needed, abrasive. The document describes that benzotriazole contained in the composition forms a reaction-protective film with an oxidized metal film to allow mechanical polishing preferentially to protruded portions, thereby enhancing flatness, and to suppress dishing.

Japanese Patent Application Laid-Open (kokai) No. 9-55363 discloses a metal-polishing composition containing 2-quinolinecarboxylic acid, which reacts with copper to form a copper complex having poor solubility in water and poor mechanical strength as compared with copper.

Japanese Patent Application Laid-Open (kokai) No. 2002-134444 discloses that a slurry containing ceria and vinylpyrrolidone/vinylimidazole copolymer is employed for polishing a metallic substrate such as copper. However, the slurry described in Patent document 4 is provided for use in polishing silica film, and the document describes no working examples of the surry applied to polishing metal film. Thus, it is apparent that a metal film cannot be virtually polished by use of such a slurry composition.

The metal-polishing composition as described in Japanese Patent Application Laid-Open (Kokai) No. 8-83980 containing benzotriazole effectively provides a flat surface and prevents dishing. However, polishing rate detrimentally decreases due to strong anti-corrosion effect of benzotriazole. The polishing composition as described in Japanese Patent Application Laid-Open (Kokai)-No. 9-55363 containing 2-quinolinecarboxylic acid is not preferred for industrial use, since 2-quinolinecarboxylic acid is a remarkably expensive material.

In recent years, use of an inter layer dielectric formed of a low-κ material has been studied, in consideration of parasitic capacitance of copper wiring. In this connection, a variety of inorganic and organic low-κ materials have been developed, and in the future such low-κ materials will require a dielectric constant of less than 2.3. In order to attain such a dielectric constant, a porous low-κ material must be provided. Up-to-Date CMP Process and Material Technology (published by Technical Information Institute Co., Ltd., 2002), p. 133 discloses that such a porous low-κ material has poor mechanical strength and is problematically broken under conventionally employed CMP pressure, thereby imposing a requirement of polishing at low pressure. However, the aforementioned conventional technique was intended to be developed for high-pressure polishing, and high-speed polishing under low pressure has never been studied.

Furthermore, in recent years, the width of wiring tends to be narrower. In the case where fine wiring lines are present at high density, a barrier film and an inter layer dielectric are over-polished to form excavated portions (i.e., phenomenon so-called erosion). Similar to dishing, erosion causes a drop in resistance of wiring as well as short circuit of wiring. Thus, prevention of these phenomena is a problem to be solved.

Thus, an object of the present invention is to provide a polishing composition which allows high-speed polishing while etching and erosion are prevented and the flatness of metal film is maintained. Another object of the invention is to provide a method for polishing metal film by use of the polishing composition. Still another object is to provide a method for producing a substrate comprising a step of planarizing the substrate by use of the polishing composition.

### SUMMARY OF THE INVENTION

The present inventors have carried out extensive studies in order to attain the above objects, and have found that the problems can be solved by a polishing composition containing a compound having three or more azole moieties. The present invention has been accomplished on the basis of this finding.

Accordingly, the present invention is directed to the following [1] to [39].

[1] A polishing composition, comprising (A) a compound having three or more azole moieties, (B) an oxidizing agent, and (C) one or more species selected from among an amino acid, an organic acid, and an inorganic acid.

[2] The polishing composition as recited in [1] above, wherein the compound having three or more azole moieties (A) is a polymer of an azole having a vinyl group.

[3] The polishing composition as recited in [1] or [2] above, wherein the compound having three or more azole moieties (A) is soluble in water.

[4] The polishing composition as recited in any one of [1] to [3] above, wherein the compound having three or more azole moieties (A) has a mass average molecular mass in a range of 300 to 5,000,000.

[5] The polishing composition as recited in any one of [1] to [4] above, wherein the content of the compound having three or more azole moieties (A) is in a range of 0.001 to 1 mass %.

[6] The polishing composition as recited in any one of [1] to [5] above, wherein amino acid comprises at least one species selected from the group consisting of glycine, L-alanine, β-alanine, L-2-aminobutyric acid, L-norvaline, L-valine, L-leucine, L-norleucine, L-isoleucine, L-allo-isoleucine, L-phenylalanine, L-proline, sarcosine, L-ornithine, L-lysine, taurine, L-serine, L-threonine, L-allo-threonine, L-homoserine, L-tyrosine, 3,5-diiodo-L-tyrosine, β-(3,4-dihydroxyphenyl)-L-alanine, L-thyroxine, 4-hydroxy-L-proline, L-cysteine, L-methionine, L-ethionine, L-lanthionine, L-cystathionine, L-cystine, L-cysteic acid, L-aspartic acid, L-glutamic acid, S-(carboxymethyl)-L-cysteine, 4-aminobutyric acid, L-asparagine, L-glutamine, azaserine, L-arginine, L-canavanine, L-citrulline, δ-hydroxy-L-lysine, creatine, L-kynurenine, L-histidine, 1-methyl-L-histidine, 3-methyl-L-histidine, ergothioneine, and L-tryptophan.

[7] The polishing composition as described in any one of [1] to [6] above, wherein the organic acid comprises at least one species selected from the group consisting of formic acid, acetic acid, propionic acid, butyric acid, valeric acid, 2-methylburyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid.

[8] The polishing composition as recited in any one of [1] to [7] above, wherein the inorganic acid is sulfuric acid, nitric acid, phosphoric acid, or a salt thereof.

[9] The polishing composition as recited in any one of [1] to [7] above, wherein the content of the one or more species selected form the group consisting of an amino acid, an organic acid and an inorganic acid (C) is in a range of 0.001 to 10 mass %.

[10] The polishing composition as recited in any one of [1] to [9] above, wherein the oxidizing agent comprises at least one species selected from the group consisiting of oxygen, ozone, hydrogen peroxide, alkyl, peroxides, peracids, permanganate salts, periodate salts, persulfate salts, polyoxo acids, and hypochlorite salts.

[11] The polishing composition as recited in any one of [10] above, wherein the content of the oxidizing agent (B) is in a range of 0.01 to 30 mass %.

[12] The polishing composition as recited in any one of [1] to [11] above, which further contains a surfactant.

[13] The polishing composition as recited in [12] above, wherein the surfactant comprises at least one species selected from the group consisting of anionic surfactants, cationic surfactants, nonionic surfactants, and ampholytic surfactants.

[14] The polishing composition as recited in [13] above, wherein the surfactant is at least one species selected from the group consisting of an alkylaromatic-sulfonic acid or a salt thereof, polyoxyethylene alkyl phosphoric acid or a salt thereof, alkyl phophoric acid or a salt thereof, and a fatty acid or a salt thereof.

[15] The polishing composition as recited in any one of [1] to [14] above, wherein the content of the surfactant is in a range of 5 mass % or less.

[16] The polishing composition as recited in any one of [1] to [15] above, which further contains a protective-film-forming agent.

[17] The polishing composition as recited in [16] above, wherein the content of the protective-film-forming agent is in a range of 5 mass % or less.

[18] The polishing composition as recited in [17] above, wherein the protective-film-forming agent comprises at least one species selected from the group consisting of benzotriazole, tolyltriazole, hydroxybenzotriazole, carboxybenzotriazole, benzimidazole, tetrazole, and quinaldinic acid.

[19] The polishing composition as recited in [18] or [19] above, wherein the content of the protective-film-forming agent is in a range of 10 mass % or less.

[20] The polishing composition as recited in any one of [1] to [19] above, which further contains an alkali substance.

[21] The polishing composition as recited in [20] above, wherein the alkali substance comprises at least one species selected from the group consisting of ammonia, amines, polyamines, alkali metal compounds, and alkaline earth metal compounds.

[22] The polishing composition as recited in [20] above, wherein the content of the alkali substance is in a range of 10 mass % or less.

[23] The polishing composition as recited in any one of [1] to [22] above, which further comprises an abrasive.

[24] The polishing composition as recited in [23] above, wherein the abrasive comprises at least one species selected from the group consisting of silica, alumina, ceria, titania, and organic abrasive.

[25] The polishing composition as recited in [23] above, wherein the content of the abrasive is in a range of 30 mass % or less.

[26] The polishing composition as recited in any one of [1] to [25] above, which has a pH of 5 to 11.

[27] The polishing composition as recited in any one of [1] to [26] above, which is used for polishing a metal film provided on a substrate having trenches such that the metal film fills the trenches.

[28] The polishing composition as recited in any one of [1] to [26] above, wherein a ratio (P_{RR}/B_{RR}), between a metal film polishing rate (P_{RR}) for polishing a metal film formed on a substrate having trenches such that the metal film fills the trenches, or polishing a metal film formed on a substrate having trenches and a barrier metal film formed on the substrate such that the metal film fills the trenches, and a metal film polishing rate (B_{RR}) for polishing a flat blanket metal film, is 3.5 or more.

[29] A composition which forms the polishing composition as set forth in any one of [5], [9], [11], [15], [17], [19], [22] and [25] above by dilution.

[30] A kit comprising a plurality of compositions, which forms the polishing composition as set forth in any one of [1] to [28] above by mixing or by mixing and dilution.

[31] A polishing method comprising forming a metal film provided on the substrate such that the metal film fills the trenches, by use of the polishing composition as set forth in any one of [1] to [27] above.

[32] A polishing method comprising forming a barrier metal film on a substrate having trenches, and polishing, by use of the polishing composition as recited in any one of [1] to [27] above, a metal film provided on the substrate such that the metal film fills the trenches.

[33] A polishing method comprising a metal film, wherein a metal film formed on a substrate having trenches such that the metal film fills the trenches, or a metal film formed on a substrate having trenches and a barrier metal film formed on the substrate such that the metal film fills the trenches, has protrusions, and corners of the protrusions are preferentially polished by the composition as se t forth in any one of [1] to [27] above.

[34] The polishing method as recited in [33] above, wherein the metal film comprises copper, a copper-containing alloy, iron, or an iron-containing alloy.

[35] The polishing method as recited in [33] or [34] above, wherein the barrier metal film comprises tantalum-containing metal such as tantalum or tantalum nitride.

[36] The method for polishing a substrate, the method comprising planarizing, by use of the polishing composition as recited in any one of [1] to [28] above, a metal film provided on a substrate having trenches such that the metal film fills the trenches.

[37] The method for producing a substrate, the method comprising a step of polishing, through the polishing method as recited in any one of [31] to [36] above, a metal film provided on a substrate having trenches such that the metal film fills the trenches.

[38] A method for using the composition as set forth in [29] above, as a transportation or storage composition.

[39] A method for using the composition as set forth in [30] above, for transportation or storage compositions.

### BRIEF DESCRIPTION OF DRAWINGS

FIG. 1 shows transverse cross-sections illustrating polishing steps of a patterned wafer.

FIG. 2 shows a transverse cross-section illustrating dishing.

FIG. 3 is a transverse cross-section illustrating erosion.

FIG. 4 shows change in the polishing rate for a copper pattern in an Example.

FIG. 5 shows the shape of corners of protrusions of a metal film polished in Examples and Comparative Examples.

### BEST MODES FOR CARRYING OUT THE INVENTION

Modes for carrying out the present invention will next be described in detail.

The polishing composition of the present invention comprises a compound having three or more azole moieties, an oxidizing agent, and one or more species selected from among an amino acid, an organic acid, and an inorganic acid. The composition is preferably employed for polishing metal film.

The compound having three or more azole moieties in its molecule employed in the present invention may be produced through any of a variety of methods. Some azole compounds such as imidazoles, triazoles, tetrazoles, and thiazoles include compounds having a reactive substituent such as a hydroxyl group, a carboxyl group, or an amino group. Examples of such azole compounds include 4-carboxyl-1H-benzotriazole, 4-hydroxybenzotriazloe, and 2-aminoimidazole. Among the reactive substituents, the carboxyl group reacts with polyhydric alcohol or polyvalent amine, to thereby form the corresponding ester or amide. When a polyhydric alcohol or a polyvalent amine having three or more functionalities is used, a compound having three or more azole moieties can be produced. Alternatively, an azole compound having a hydroxyl group or an amino group is reacted with a compound having a reactive site with respect to the hydroxyl group or amino group, to thereby produce a compound having three or more azole moieties.

Alternatively, a compound having three or more azole moieties may be produced through polymerization of an azole compound having a vinyl group. Examples of the vinyl-group-containing azole compound include 1-vinylimidazole, 2-[3-(2H-benzotriazol-1-yl)-4-hydroxyphenyl]ethyl methacrylate.

Among compounds having three or more azole moieties, compounds produced by polymerizing an azole compound having a vinyl group are preferred. The polymer may be a homopolymer or a copolymer with another vinyl compound.

Examples of the vinyl compound which can copolymerize with an azole compound having a vinyl group include acrylic acid, methacrylic acid, methyl acrylate, methyl methacrylate, acrylamide, N-vinylacetamide, N-vinylformamide, acryloylmorpholine, N-vinylpyrrolidone, vinyl acetate, and styrene.

The above vinyl compounds are generally polymerized through-radical polymerization in an aqueous solution or an organic solvent. Radical polymerization is typically performed in the presence of an initiator such as azobisisobutyronitrile, and a chain transfer agent such as dodecylmercaptan, trimethylolpropanetris(3-mercaptopropionate), or a-methylstyrene dimer may also be used to control molecular weight of the product.

The thus-produce polymer employable in the present invention has a weight average molecular weight of preferably 300 to 5,000,000, more preferably 1,000 to 1,000,000, further preferably 2,000 to 300,000, particularly preferably 2,000 to 200,000.

The compound having three or more azole moieties employable in the present invention is incorporated into the-polishing composition in an amount of preferably 0.001 to 1 mass %, more preferably 0.002 to 0.5 mass %, particularly preferably 0.003 to 0.1 mass %. When the amount is small, etching prevention and enhancement of polishing rate is insufficiently attained, whereas when the amount is large, the effect commensurate with addition cannot be attained and, in some cases, aggregation of abrasive added may be promoted.

The polishing composition of the present invention may be employed in any form of an organic-solvent-based composition, an organic solvent/water-based composition, and an aqueous composition. From the viewpoint of safety, cost, and handling, the polishing composition is preferably in the form of aqueous solution. In this connection, the compound having three or more azole moieties is preferably water-soluble. When a concentrated liquid of the compound having three or more azole moieties is prepared and the concentrate is then diluted to prepare a target composition, it is convenient in handling. Therefore, the compound having three or more azole moieties preferably has a water solubility of 0.01 mass % or more, more preferably 0.03 mass % or more.

The azole moiety of the compound employed in the present invention is known to exert interaction with metal such as copper. This interaction is considered to enhance step reduction and dishing prevention effect. The compound having three or more azole moieties can appropriately regulate the polishing rate for a barrier film such as tantalum film. The effect is considered to enhance erosion prevention effect. In general, a basic compound such as ethanolamine, which regulates polishing rate for a barrier film such as tantalum film and enhances erosion prevention effect, rather impairs step reduction and dishing prevention effect. However, according to the present invention, a complicated effect is provided by use of a compound having a plurality (three or more) of azole moieties, and the effect is considered to simultaneously attain enhancement of step reduction, prevention of dishing, and prevention of erosion, which conflict one another.

The inorganic acid, organic acid, and amino acid which may be incorporated into the polishing composition of the present invention serves as an etchant for promoting polishing and for performing reliable polishing. Examples of the inorganic acid, organic acid, and amino acid include inorganic acids such as sulfuric acid, phosphoric acid, phosphonic acid, and nitric acid; carboxylic acids such as formic acid, acetic acid, propionic acid, butyric acid, valeric acid, 2-methylburyric acid, n-hexanoic acid, 3,3-dimethylbutyric acid, 2-ethylbutyric acid, 4-methylpentanoic acid, n-heptanoic acid, 2-methylhexanoic acid, n-octanoic acid, Z-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid, and salts thereof; and amino acids such as glycine, L-alanine, β-alanine, L-2-aminobutyric acid, L-norvaline, L-valine, L-leucine, L-norleucine, L-isoleucine, L-allo-isoleucine, L-phenylalanine, L-proline, sarcosine, L-ornithine, L-lysine, taurine, L-serine, L-threonine, L-allo-threonine, L-homoserine, L-tyrosine, 3,5-diiodo-L-tyrosine, β-(3,4-dihydroxyphenyl)-L-alanine, L-thyroxine, 4-hydroxy-L-proline, L-cysteine, L-methionine, L-ethionine, L-lanthionine, L-cystathionine, L-cystine, L-cysteic acid, L-aspartic acid, L-glutamic acid, S-(carboxymethyl)-L-cysteine, 4-aminobutyric acid, L-asparagine, L-glutamine, azaserine, L-arginine, L-canavanine, L-citrulline, δ-hydroxy-L-lysine, creatine, L-kynurenine, L-histidine, 1-methyl-L-histidine, 3-methyl-L-histidine, ergothioneine, and L-tryptophan.

These inorganic acids, organic acids, and amino acids may be used singly or in combination of two or more species. The total amount of these acids is preferably 0.01 to 10 mass % based on the polishing composition, more preferably 0.02 to 5 mass %, particularly preferably 0.05 to 2 mass %. When the amount is small, appropriate polishing rate cannot be attained, whereas when the amount is large, etching rate for metal or alloy is excessively increases, thereby failing to attain planarization and prevention of dishing.

The oxidizing agent employed in the polishing composition of the present invention oxidizes metal or alloy, thereby enhancing polishing rate. Examples of the oxidizing agent include oxygen, ozone, hydrogen peroxide, alkyl peroxides (e.g., t-butyl hydroperoxide and ethylbenzene hydroperoxide), peracids (e.g., peracetic acid and perbenzoic acid), permanganate salts (e.g., potassium permanganate), periodate salt (e.g., potassium periodate), persulfate salts (e.g., ammonium persulfate and potassium persulfate), hypochlorite salts (e.g., potassium hypochlorite), and polyoxo acids. Among these oxidizing agents, hydrogen peroxide and persulfate salts, which can be simply handled, are preferred.

The amount of the oxidizing agent is preferably 0.01 to 30 mass % with respect to the polishing composition, more preferably 0.05 to 20 mass %, particularly preferably 0.1 to 10 mass %. When the amount is small, polishing rate is poor, thereby failing to sufficiently attain the effect of the agent added. A large amount thereof is economically disadvantageous and, in some cases, may reduce polishing rate.

In addition to the compound having three or more azole moieties employed in the present invention, a water-soluble polymer or a surfactant may be incorporated into the polishing composition of the present invention in accordance with needs. Examples of the water-soluble polymer include poly(acrylic acid), poly(methacrylic acid), ammonium salts thereof, polyisopropylacrylamide, polydimethylacrylamide, polymethacrylamide, polymethoxyethylene, poly(vinyl alcohol), hydroxyethyl cellulose, carboxymethyl cellulose, carboxyethyl cellulose, and polyvinylpyrrolidone. In the present invention, any of anionic surfactants, cationic surfactants, and nonionic surfactants may be employed. Examples of the cationic surfactants include aliphatic amines or salts thereof and aliphatic ammonium salts. Examples of the anionic surfactants include fatty acids such as undecylic acid, myristic acid, stearic acid, sostearic acid and oleic acid, and salts thereof (fatty acid soap); alkyl ether carboxylic acids and salts thereof; sulfonic acid compounds such as alkylbenzenesulfonic acids and salts thereof and alkylnaphthalenesulfonic acids and salts thereof; sulfate ester compounds (e.g., higher alcohol sulfate esters, and alkyl ether sulfuric acids and salts thereof), and phosphoric acid compounds (polyoxyethylene lauryl ether phosphate, polyoxyethylene oleic ether phosphate, polyoxyethylene alkyl ether phosphate esters, polyoxyethylene secondary alkyl ether phosphate esters and lauryl phosphate and salts thereof). Examples of the non-ionic surfactants include ether species (e.g., polyoxyethylene alkyl ethers), ether-ester species (e.g., glycerin ester polyoxyethylene ethers), and ester species (e.g., polyethylene glycol fatty acid esters, glycerin esters, and sorbitan esters). These aqueous polymers or surfactants may be added alone or in combination. Among these water-soluble polymers and surfactants, sulfonate compound surfactants, fatty acid surfactants and phosphoric acid compound surfactants are preferred, with alkylbenzenesulfonic acids having a C≧8 alkyl group and salts thereof, fatty acid surfactants having a C≧8 alkyl group and salts and phosphoric acid compound surfactants having a C≧8 alkyl group and salts being more preferred. The water-soluble polymer or the surfactant is incorporated into the polishing composition in an amount of preferably 5 mass % or less, more preferably 1 mass % or less, particularly preferably 0.5 mass % or less.

Into the polishing composition of the present invention, an anti-corrosion agent (protective-film-forming agent) may be incorporated. Examples of preferred components include azoles such as benzimidazole-2-thiol, 2-[2-(benzothiazolyl)]thiopropionic acid, 2-[2-(benzothiazolyl)]benzothiazolyl thiobutyric acid, 2-mercaptobenzothiazole, 1,2,3-triazole, 1,2,4-triazole, 3-amino-1H-1,2,4-triazole, benzotriazole, 1-hydroxybenzotriazole, 1-dihydroxypropylbenzotriazole, 2,3-dicarboxypropylbenzotriazole, 4-hydroxybenzotriazole, 4-carboxyl-1H-benzotriazole, 4-methoxycarbonyl-1H-benzotriazole, 4-butoxycarbonyl-1H-benzotriazole, 4-dctyloxycarbonyl-1H-benzotriazole, 5-hexylbenzotriazole, N-(1,2,3-benzotriazolyl-1-methyl)-N-(1,2, 4-triazolyl-1-methyl)-2-ethylhexylamine, tolyltriazole, naphthotriazole, bis[(1-benzotriazolyl)methyl]phosphonic acid, benzimidazole, and tetrazole, and salts thereof. More preferred components include benzotriazole, tolyltriazole, hydroxybenzotriazole, carboxybenzotriazloe, benzimidazole, tetrazole, and quinaldinic acid. The amount of the anti-corrosion agent incorporated into the composition is preferably 5 mass % or less, more preferably 2 mass % or less, particularly preferably 0.5 mass % or less.

The polishing composition of the present invention may contain an alkali substance so long as the performance and physical properties of the composition are not impaired. The alkali substance is added so as to maintain reliable polishing performance and serves as a pH regulator or a buffer. Examples of the alkali substance include ammonia; sodium hydroxide; potassium hydroxide; potassium carbonate; potassium hydrogencarbonate; ammonium hydrogencarbonate; alkylmonoamines such as methylamine, ethylamine, propylamine, isopropylamine, butylamine, isobutylamine, t-butylamine, amylamine, allylamine, 2-ethylhexylamine, cyclohexylamine, benzylamine, furfurylamine and tetrahydrofurfurylamine; monoamines having a hydroxyl group such as o-aminophenol, ethanolamine, 3-amino-1-propanol, and 2-amino-1-propanol; diamines such as ethylenediamine, 1,2-propyrene diamine, 1,3-propyrene diamine, o-phenylenediamine, trimethylenediamine, 2-methyl-2-(2-benzylthioethyl)ethylenediamine, 1,5-diamino-3-pentanol, 1,3-diamino-2-propanol, xylenediamine, and bisaminopropylpolyalkylene ether; and polyamines such as diethylenetriamine, triethylenetetramine, tetraethylenepentamine, pentaethylenehexamine, 2,2-diamino-di-n-propylamine, polyallylamine and polyethyleneimine. Of these, ammonia, diamine and potassium hydroxide are preferred. The amount of the alkali substance incorporated in the polishing composition is referably 10 mass % or less, more preferably 5 mass % or less, particularly preferably 1 mass % or less.

The polishing composition of the present invention may be employed without use of abrasive. However, in order to sufficiently increase polishing rate, abrasive may be incorporated into the composition. Examples of the abrasive include silica, alumina, ceria, and organic abrasive. These abrasive may be used singly or in combination of two or more species. The abrasive incorporated into the polishing composition in an amount of preferably 30 mass % or less, more preferably 20 mass % or less, particularly preferably 10 mass % or less, since an excessively large amount thereof causes dishing and increases scratches.

The polishing composition employed in the present invention can be used within a pH range of preferably 2 to 12. The pH range is more preferably 3 to 11, particularly preferably 5 to 10. The pH may be adjusted by use of the aforementioned inorganic acid, organic acid, or alkali substance.

The composition of the present invention has an improved step reduction effect when a ratio (P_{RR}/B_{RR}), between a metal film polishing rate (P_{RR}) for polishing a metal film formed on a substrate having trenches such that the metal film fills the trenches, or polishing a metal film formed on a substrate having trenches and a barrier metal film formed on the substrate such that the metal film fills the trenches, and a metal film polishing rate (B_{RR}) for polishing a flat blanket metal film, is 3.5 or more. That is, when a metal layer having protrusions and trenches is polished, an initial polishing rate is high due to the protrusions and trenches but, as the polishing proceeds and the protrusions and trenches disappear, the polishing rate decreases. The polishing rate finally becomes the same as the polishing rate for polishing a flat blanket metal film. If the polishing rate for polishing a flat blanket metal film is significantly small, as the protrusions and trenches of a substrate disappear, the polishing rate becomes small and, finally, the substrate having protrusions and trenches become flat and the polishing almost does not proceed;

When a metal film formed on a substrate having trenches such that the metal film fills the trenches, or a metal film formed on a substrate having trenches and a barrier metal film formed on the substrate such that the metal film fills the trenches, has protrusions, if the corners of the protrusions are preferentially polished by a composition of the present invention, the step reduction is further improved. While the corners of protrusions of a metal film having protrusions and trenches are generally subjected to shearing and thus prone to be polished, in the case of the composition of the present invention, the corners are further prone to be polished and thus the step reduction effect is further enhanced.

Of course, when a ratio (P_{RR}/B_{RR}), between a metal film polishing rate (P_{RR}) for polishing a metal film formed on a substrate having trenches such that the metal film fills the trenches, or polishing a metal film formed on a substrate having trenches and a barrier metal film formed on the substrate such that the metal film fills the trenches, and a metal film polishing rate (B_{RR}) for polishing a flat blanket metal film, is 3.5 or more, as well as a metal film formed on a substrate having trenches such that the metal film fills the trenches, or a metal film formed on a substrate having trenches and a barrier metal film formed on the substrate such that the metal film fills the trenches, has protrusions, and the corners of the protrusions are preferentially polished, the step reduction is further improved.

The polishing composition of the present invention may be preferably used in a temperature range of 0 to 100° C. In general, the composition is preferably used at about room temperature. However, the temperature of the polishing composition may be modified for the purpose of, for example, control of polishing rate. When the temperature is too low, polishing rate cannot be increased, and the polishing liquid may be solidified at a temperature below 0° C., whereas when the temperature is excessively high, side reaction may occur. Thus, the temperature is more preferably 10 to 50° C., particularly preferably 15° C. to 40° C.

The amount of the polishing composition added dropwise to a polishing machine is determined in accordance with the dimensions of the polishing machine employed and the wafer to be polished. When an 8-inch wafer is polished, an amount of preferably 10 to 1,000 mL/min may be employed. The amount is more preferably 50 to 500 mL/min, particularly preferably 100 to 400 mL/min.

The polishing composition of the present invention is preferably used for polishing metal. Examples of preferred metals include aluminum, copper, iron, tungsten, nickel, tantalum, platinum-group metals such as ruthenium and platinum, and alloys of the metals. In a particularly preferred mode, the metal film serves as a wiring portion of a multi-layer wiring portion or covers the wiring portion. The metal film is provided on a surface of a substrate having trenches such that the trenches are filled with the metal film. More preferably, the wiring portion of a multi-layer wiring portion is made from copper, copper alloy, iron, or iron alloy. In some cases, a barrier layer may be inserted between the metal wiring layer and the substrate. In this case, the barrier film can be generally polished together with the metal film. Examples of materials preferably employed for forming the barrier film include tantalum, tantalum alloys, tantalum nitride, titanium, and titanium alloys.

In the polishing method employing the polishing composition of the present invention, a workpiece having, for example, a metal film to be polished is pressed against a polishing pad affixed to a platen. While the polishing composition of the present invention is fed between the polishing pad and the substrate, relative rotation between the platen and the substrate is effected, thereby polishing the workpiece. In this case, any conventional polishing machine having a holder for holding a semiconductor substrate and a platen onto which a polishing pad is affixed may be employed. The rotation speed of the platen varies considerably depending on the structure and dimensions of the polishing machine employed and, therefore, the rotation speed cannot be predetermined definitively. However, the peripheral speed is preferably 10 to 500 m/min, more preferably 20 to 300 m/min, particularly preferably 30 to 150 m/min. In order to perform uniform polishing of the substrate through rotation of the platen, the substrate must be rotated. The substrate is rotated at a speed almost equal to that of the platen and, in some cases, the rotation speed may be slightly modified (accelerated or retarded) so as to accomplish uniform polishing. The substrate is pressed against the polishing pad by means of, a holder for holding the substrate. The pressure may be preferably 0.1 to 100 kPa. The pressure cannot be predetermined definitively, because when the rotation speed of the surface-substrate is high, the pressure is prone to decrease. However, the pressure is more preferably 0.5 to 80 kPa, particularly preferably 1 to 50 kPa.

The polishing pad employed in the present invention is generally made of non-woven fabric or polyurethane foam. Most polishing pads have grooves so as to accelerate polishing and to facilitate discharge of a polishing slurry. Examples of such grooves include XY groove and K groove. The polishing composition of the present invention is applicable to any of these grooved polishing pads. Polishing pads are generally dressed by means of a diamond dresser so as to prevent clogging and to perform reliable polishing. In the present invention, any conventionally known dressing method may be employed.

The polishing composition of the present invention is continuously supplied onto the polishing pad affixed on the platen, by use of a pump or a similar apparatus. The polishing composition to be supplied may be in the form of a single liquid containing all ingredients. Alternatively, the composition may be supplied in the form of an oxidizing agent such as hydrogen peroxide solution and other solutions via separated lines, in consideration of stability of the polishing liquid. When a plurality of liquid components are supplied via separated lines, these components may be combined to form a single liquid just before supply to the polishing cloth, or may be supplied on the polishing cloth separately via individual lines.

Through the aforementioned polishing method, a substrate having a planerized metal film can be produced. The step will be next be described in more detail, by reference to an example of formation of a wiring on a device element. First, trenches and openings for wiring are provided in an inter layer dielectric affixed onto a substrate, and a thin barrier layer is formed on the insulating film. Subsequently, a metal (e.g., copper) wiring layer for providing wiring is formed, through plating or a similar method, such that the trenches and openings are filled with the metal wiring layer. The metal layer is polished and, if required, the barrier layer and the inter layer dielectric are planarization-polished, to thereby form a substrate having a flat metal film on a surface thereof. The wiring method employed in MRAMs will next be described. The metal wiring provided in an MRAM includes a conductor layer composed of aluminum or aluminum alloy, and copper or copper alloy; and a ferromagnetic layer composed of nickel-iron (permalloy) and covering the conductor layer. If needed, a thin barrier film composed of a certain material (e.g., tantalum or tantalum nitride) is formed on the ferromagnetic layer. The metal wiring is formed through the damascene method, and excess portions of the conductor layer, the ferromagnetic layer, and the barrier film are removed through polishing performed in parallel, thereby providing a planar surface.

In the present invention, the inter layer dielectric includes an inorganic inter layer dielectric having high silicon content such as silicon oxide film, hydroxysilsesquioxane (HSQ), or methylsilsesquioxane (MSQ), and an organic inter layer dielectric such as a benzocyclobutene film. These films may incorporate pores, to thereby serve as low-dielectric-constant inter layer dielectrics.

### EXAMPLES

The present invention will next be described in more detail by way of examples, which should not be construed as limiting the invention thereto.

### Synthesis Examples

Synthesis Examples of compounds having three or more azole moieties will next be described. Needless to say, these examples are not construed as limiting the invention thereto.

<Compound A>

To a 100-mL three-neck flask equipped with a stirring paddle, a thermometer, and a reflux condenser, 1-propanol (42 g), an azo-type initiator (4.61 g) (V-601, product of Wako Pure Chemicals Industries, Ltd.), 1-vinylimidazole (9.41 g), and n-dodecylmercaptan (4.05 g) serving as a chain transfer agent were fed, while nitrogen was fed to the flask through the reflux condenser. The mixture was stirred well for dissolution of components. The solution was stirred for 30 minutes at room temperature, followed by elevating the temperature to 80° C. Reaction was continued for five hours at the temperature. The reaction mixture was further stirred at 90° C. for two hours, followed by cooling to room temperature. The solution was added dropwise to n-hexane (500 mL), to thereby form precipitates. The precipitates were removed through filtration and dried at 50° C. for 24 hours in vacuum, to thereby yield compound A.

<Compound B>

To a 200-mL three-neck flask equipped with a stirring paddle, a thermometer, and a reflux condenser, 1-propanol (58.3 g), an azo-type initiator (1 g) (V-601, product of Wako Pure Chemicals Industries, Ltd.), 1-vinylimidazole (25 g), and α-methylstyrene dimer (1.04 g) serving as a chain transfer agent were fed, while nitrogen was fed to the flask through the reflux condenser. The mixture was stirred well for dissolution of components. The solution was stirred for 30 minutes at room temperature, followed by elevating the temperature to 80° C. Reaction was continued for five hours at the temperature. The reaction mixture was further stirred at 90° C. for two hours, followed by cooling to room temperature. The solution was added dropwise to n-hexane (1,000 mL), to thereby form precipitates. The precipitates were removed through filtration and dried at 50° C. for 24 hours in vacuum, to thereby yield compound B.

<Compound C>

To a 1,000-mL three-neck flask equipped with a stirring paddle, a thermometer, and a reflux condenser, dimethylformamide (400 g), an azo-type initiator (5 g) (V-601, product of Wako Pure Chemicals Industries, Ltd.), and 1-vinylimidazole (100 g) were fed, while nitrogen was fed to the flask through the reflux condenser. The mixture was stirred well for dissolution of components. The solution was stirred for 30 minutes at room temperature, followed by elevating the temperature to 100° C. Reaction was continued for three hours at the temperature. Subsequently, a solution of V-601 (5 g) dissolved in dimethylformamide (10 g) was added dropwise to the reaction mixture, and the mixture was stirred at 100° C. for three hours, followed by cooling to room temperature. The solution was added dropwise to tetrahydrofuran (2,000 mL), to thereby form precipitates. The precipitates were removed through filtration and dried at 50° C. for 24 hours in vacuum, to thereby yield compound C.

<Compound D>

To a 1,000-mL three-neck flask equipped with a stirring paddle, a thermometer, and a reflux condenser, water (400 g), an azo-type initiator (5 g) (VA-086, product of Wako Pure Chemicals Industries, Ltd.), and 1-vinylimidazole (100 g) were fed, while nitrogen was fed to the flask through the reflux condenser. The mixture was stirred well for dissolution of components. The solution was stirred for 30 minutes at room temperature, followed by elevating the temperature to 100° C. Reaction was continued for three hours at the temperature. Subsequently, a solution of VA-086 (5 g) dissolved in water (10 g) was added dropwise to the reaction mixture, and the mixture was stirred at 100° C. for three hours, followed by cooling to room temperature. At this stage, the mixture was measured to have a solid content of 21.4%. Compound D was not isolated from the mixture, and the mixture was subjected to subsequent tests.

(Compound E)

To a 500-mL flask equipped with a thermometer, a stirrer, a nitrogen conduit, and a reflux condenser, 2-propanol (40g) was fed and the temperature was elevated under nitrogen atmosphere while stirring to 75° C. To this, a solution of 1-vinylimidazole (46.31 g) and 1-vinylpyrrolidone (43.69g) dissolved in 2-propanol (78g) (hereinafter referred to as “a monomer solution”) and a solution of dimethyl-2,2′-azobis(2-methylpropionate) (4.08g) in 2-propanol (163.92g) (hereinafter referred to as “initiator solution 1”) were added through a metering pump, respectively. The addition times were 4 hours for the monomer solution and 6 hours for the initiator solution 1. After the initiator solution 1 was added, the temperature of the reaction solution was elevated to the refluzing temperature (about 83° C.). Further a solution of dimethyl-2,2′-azobis(2-methylpropionate) (2.04 g) in 2-propanol (38.76 g) (hereinafter referred to as “initiator solution 2”) were added to the mixture and the reaction was continued for 7.5 hours. After the reaction solution was cooled to room temperature, a clear brawn solution (about 415 g) was obtained. The clear brawn solution was condensed through a rotary vacuum evaporator and dissolved in water, which was repeated twice, to replace the solvent from 2-propanol to water. The mixture had a solid content of 15 mass %. The product was used as was without isolation to prepare a slurry.

(Compound F)

To a 500-mL flask equipped with a thermometer, a stirrer, a nitrogen conduit, and a reflux condenser, 2-propanol (30 g) was fed and the temperature was elevated under nitrogen atmosphere while stirring to a refluxing temperature (about 83° C.). To this, a solution of 1-vinylimidazole (46.31 g), 1-vinylprrolidone (43.69 g) and α-methyl styrene dimer (0.84 g) dissolved in 2-propanol (77.2 g) (hereinafter referred to as “a monomer solution”) and a solution of dimethyl-2,2′-azobis(2-methylpropionate) (3.26 g) in 2-propanol (164.74 g) (hereinafter referred to as “initiator solution 1”) were added through a metering pump, respectively. The addition times were 4 hours, respectively. After the monomer solution and the initiator solution 1 was added, the reaction was continued for 1 hour. Then a solution of dimethyl-2,2′-azobis(2-methylpropionate) (0.82 g) in 2-propanol (15.58 g) (hereinafter referred to as “initiator solution 2”) were added to the mixture. An operation of adding the same initiator solution 2 after each one hour-reaction (initiator addition operation) was repeated three times and the reaction was further continued for 4 hours. After the reaction solution was cooled to room temperature, a clear brawn solution (about 420 g) was obtained. The clear brawn solution was condensed through a rotary vacuum evaporator and dissolved in water, which was repeated twice, to replace the solvent from 2-propanol to water. The product had a solid content of 15% and was subjected to slurry preparation as was without isolation.

(Compound G)

To a 500-mL flask equipped with a thermometer, a stirrer, a nitrogen conduit, and a reflux condenser, 2-propanol (30 g) was fed and the temperature was elevated under nitrogen atmosphere while stirring to a refluxing temperature (about 98° C.). To this, a solution of 1-vinylimidazole (15.72 g), 1-vinylpyrrolidone (74.28 g) and 2-mercapto ethanol (0.066 g) dissolved in 2-propanol (29.93 g) (hereinafter referred to as “a monomer solution”) and a solution of dimethyl-2,2′-azobis(2-methylpropionate) (0.77 g) in 2-propanol (215.23 g) (hereinafter referred to as “initiator solution 1”) were added through a metering pump, respectively. The addition times were 4 hours for both the monomer solution and the initiator solution 1. After the monomer solution and the initiator solution 1 were added, the reaction was continued for 1 hour. Then a solution of dimethyl-2,2′-azobis(2-methylpropionate) (0.77 g) in 2-propanol (14.63 g) (hereinafter referred to as “initiator solution 2”) was added to the mixture and the reaction was further continued for 5 hours. After the reaction solution was cooled to room temperature, a clear brawn solution (about 380 g) was obtained. The clear brawn solution was condensed through a rotary vacuum evaporator and dissolved in water, which was repeated twice, to replace the solvent from 2-propanol to water. The product had a solid content of 15% and was subjected to slurry preparation as was without isolation.

(Compound H)

The same procedures as for synthesizing Compound G were repeated, provided that the monomer solution was a soluiton of 1-vinylimidazole (46.31 g), 1-vinylpyrrolidone (43.69 g) and 2-mercapto ethanol (0.21 g) in 2-propanol (29.79 g); the initiator solution 1 was a solution of dimethyl-2,2′-azobis(2-methylpropionate) (0.82 g) in 2-propanol (215.18 g); the initiator solution 2 was a solution of dimethyl-2,2′-azobis(2-methylpropionate) (0.82 g) in 2-propanol (15.58 g); and the initiator addition operation was repeated twice. The product had a solid content of 18% and was subjected to slurry preparation as was without isolation.

(Compound I)

To a 500-mL flask equipped with a thermometer, a stirrer, a nitrogen conduit, and a reflux condenser, 2-propanol (40 g) was fed and the temperature was elevated under nitrogen atmosphere while stirring to a refluxing temperature (about 83° C.). To this, a solution of 1-vinylimidazole (46.31 g), N-vinylpyrrolidone (43.69 g) and a-methyl styrene dimer (1.46 g) dissolved in 2-propanol (28.5 g) (hereinafter referred to as “a monomer solution”) and a solution-of dimethyl-2,2′-azobis(2-methylpropionate), (2.45 g) in 2-propanol (213.55 g) (hereinafter referred to as “initiator solution 1”) were added through a metering pump, respectively. The addition times were 4 hours for the monomer solution and 7 hours for the initiator solution 1. After the initiator solution 1 were added, the reaction was continued for 1 hour. Then a solution of dimethyl-2,2′-azobis(2-methylpropionate) (0.21 g) in 2-propanol (6.59 g) (hereinafter referred to as “initiator solution 2”) was added to the mixture. An-operation of adding the same initiator solution 2 after each one hour-reaction (initiator addition operation) was repeated five times and the reaction was then continued for 4 hours. After the reaction solution was cooled to room temperature, a clear brawn solution (about 380 g) was obtained. The clear brawn solution was condensed through a rotary vacuum evaporator and dissolved in water, which was repeated twice, to replace the solvent from 2-propanol to water. The product had a solid content of 15% and was subjected to slurry preparation as was without isolation.

<Molecular Weight Measurement>

Molecular weight of each of the synthesized compounds was determined through gel permeation chromatography (GPC) (reduced to polyethylene glycol). In the present invention, a commercial product was also employed, and molecular weight of the commercial product was also determined. The employed commercial product was VPI55K18P (hereinafter abbreviated as 18P) (1-vinylimidazole-1-vinylpyrrolidone (1:1) copolymer, product of BASF) and VPI55K72W (hereinafter abbreviated as 18P, product of BASF).

Molecular weight measurements of compounds A, B, C, D, E, F, G, H, I, 18P and 72W were determined as follows.
Compound A: 2,600
Compound B: 5,200
Compound C: 9,700
Compound D: 89,000
Compound E: 10,500
Compound F: 6,200
Compound G: 5,500
Compound H: 5,000
Compound 18P: 5,000
Compound 72W: 220,000
   <Wafer>

Blanket: Silicon wafer uniformly coated with copper film and tantalum film (barrier film)

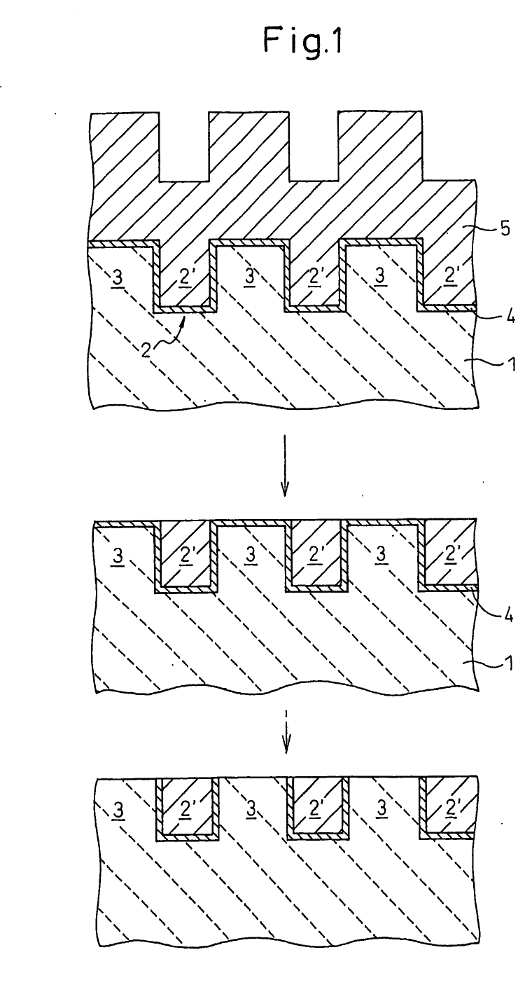

Pattern: A silicon wafer having trenches (depth: 500 nm) coated with a barrier film (thickness: 25 nm) made of tantalum, and the entire surface is coated with a copper film (1,000 nm) (see top of FIG. 1).

<Polishing of Wafer cut to 4×4 cm Pieces>

Relative speed of platen to substrate: 54 m/min

Polishing pad: IC 1000/SUBA 400 (Product of Rodel Nitta)

Polishing composition feed rate: 13 mL/min

<Polishing of 8-Inch Wafer>

Relative speed of platen to substrate: 70 m/min

Polishing pad: IC 1000/SUBA 400 (Product of Rodel Nitta)

Polishing composition feed rate: 200 mL/min

<Etching Test>

Etching rate (per minute) was obtained by immersing each copper sheet piece (2 cm×2 cm) in the respective polishing composition and measuring the amount of loss.

<Evaluation of Polishing Characteristics>

Measurement of step (depth): The depth was determined by use of a probe-type step meter.

Thickness measurement (blanket copper and tantalum film): Each thickness was determined through measurement of sheet resistance.

Thickness measurement (copper pattern film): The thickness was determined through measurement of sheet resistance of an unpatterned portion in the vicinity of the site to be evaluated.

Determination of polishing rate: Copper film thickness and barrier film thickness were determined before and after polishing, through measurement of electrical resistance. The difference was divided by polishing time.

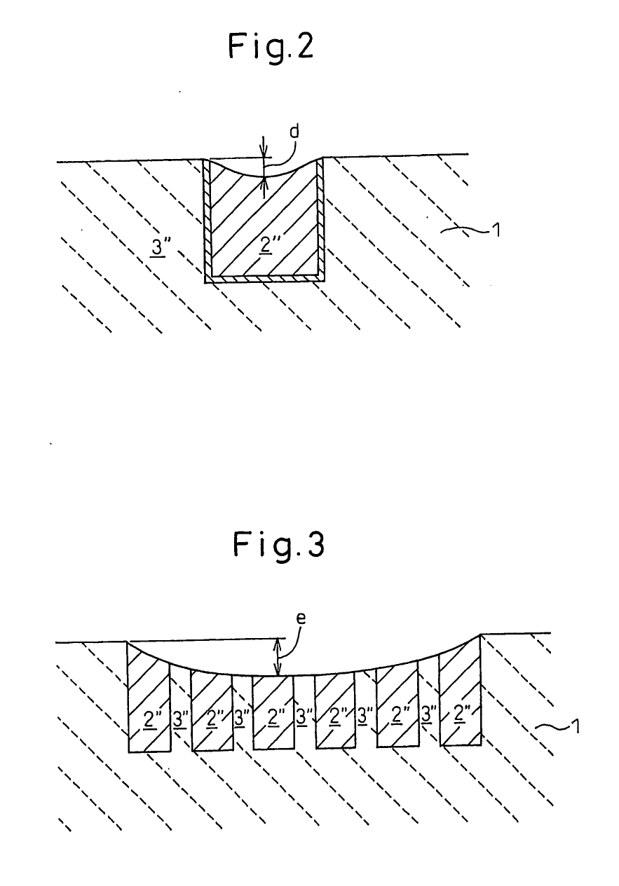

Evaluation of step reduction: The aforementioned pattered wafer (line/space, 100 μm/100 μm, see top of FIG. 1) was polished such that copper film was left on the wafer at a thickness of about 300 nm. Steps formed by polishing were observed, and the step depth was determined. The step reduction was evaluated on the basis of the following ratings: DD; steps (200 nm or more) remaining, CC; steps (200 to 100 nm remaining), BB; steps (100 to 50 nm) remaining; and AA steps (less than 50 nm) remaining. Evaluation of dishing: The polishing rate employed was determined by polishing a pattered wafer (line/space, 100 μm/100 μm, see top of FIG. 1) such that copper film was left at a thickness of about 300 nm. Through employment of the polishing rate, each wafer was polished under certain conditions; i.e., for a certain period of time so that the copper film was over-polished at a rate of 50% vs. the initial thickness (50% over-polishing of the wafer (mid of FIG. 1)). The step depth (“d” in FIG. 2) generated in a copper pattern (line/space, 100 μm/100 μm) was employed as an index for evaluating dishing. Erosion measurement: The polishing rate employed was determined by polishing a similar pattered wafer (line/space, 9 μm/1 μm) such that copper film was left at a thickness of about 300 nm. Through employment of the polishing rate, each wafer was polished under certain conditions; i.e., for a certain period of time so that the copper film was over-polished at a rate of 50% vs. the initial thickness. The loss (“e” in FIG. 3) of the barrier film and the inter layer dielectric at a space portion at a 9 μm/1 μm (line/space) was employed as an index for evaluating erosion.

### Examples 1 to 3 and Comparative Example 1

Each polishing composition was prepared by adding to water (balance of the composition) an azole compound, an acid, an amino acid, an oxidizing agent, an anti-corrosion agent, and abrasive listed in Table 1. The pH of the composition was adjusted by use of an alkali substance. The amount of each additive shown in Table 1 is mass % basis. A workpiece (cut wafer, 4×4 cm) was polished at a polishing pressure of 10 kPa.

In Table 1, APS and BTA refer to ammonium persulfate and benzotriazole, respectively. The colloidal silica contained in the composition had a particle size of 70 nm.

TABLE 1

| Ex. & | | | | | | Anti- | | | |
|---|---|---|---|---|---|---|---|---|---|
| Comp. | | | Amino | Oxidizing | | corrosion | | | |
| Ex. | Azole | Acid | acid | agent | Surfactant | agent | Alkali | Abrasive | pH |
| Ex. 1 | Compound B | Lactic | | APS | | BTA | ammonia | Colloidal | 8.5 |
| | 0.005 | acid | | 2.0 | | 0.03 | | silica | |
| | | 1.5 | | | | | | 1.0 | |
| Ex. 2 | 18P | Lactic | | APS | | BTA | ammonia | Colloidal | 8.5 |
| | 0.005 | acid | | 1.0 | | 0.03 | | silica | |
| | | 0.75 | | | | | | 1.0 | |
| Ex. 3 | 18P | Lactic | Glycine | APS | | BTA | ammonia | Colloidal | 8.5 |
| | 0.005 | acid | 0.1 | 1.0 | | 0.03 | | silica | |
| | | 0.75 | | | | | | 1.0 | |
| Comp. | | Lactic | | APS | | BTA | ammonia | Colloidal | 8.5 |
| Ex. 1 | | acid | | 2.0 | | 0.03 | | silica | |
| | | 1.5 | | | | | | 1.0 | |

As shown in Table 2, in all Examples substantially no etching occurred. Thus, the polishing compositions according to the present invention attained remarkably excellent dishing prevention and erosion prevention characteristics. In contrast, the polishing composition of Comparative Example 1 containing no azole compound did not prevent dishing, and erosion characteristics were unsatisfactory. Combination of the azole compound of the invention and an anti-corrosion agent was found to effectively prevent dishing and erosion, although step reduction was not remarkably improved. The polishing composition of Example 3, which was prepared by adding a small amount of glycine to the Example 2 composition was found to increase polishing rate and provide improved erosion prevention effect, although etching prevention effect and dishing prevention effect were slightly impaired.

TABLE 2

| | Polishing | Polishing | Polishing | | | | |
|---|---|---|---|---|---|---|---|
| Ex. & | rate, Cu | rate, Cu | rate, Ta | Step | | | |
| Comp. Ex. | (blanket) | (pattern) | (blanket) | reduction | Dishing | Erosion | Etching |
| Ex. 1 | 384 nm/min | 412 nm/min | | BB | 72 nm | 22 nm | 0 nm/min |
| Ex. 2 | 219 nm/min | 212 nm/min | | BB | 45 nm | 23 nm | 0 nm/min |
| Ex. 3 | 311 nm/min | 335 nm/min | | BB | 98 nm | 13 nm | 5 nm/min |
| Comp. Ex. 1 | 463 nm/min | 512 nm/min | | BB | 330 nm | 51 nm | 0 nm/min |

### Examples 4 to 8 and Comparative Example 2

Polishing liquids were prepared in a similar manner, but the species and amount of the azole compound was changed as shown in Table 3. The pH of each polishing liquid was adjusted by use of an alkali substance. A workpiece (cut wafer, 4×4 cm) was polished at a polishing pressure of 20 kPa. In Table 3, DBS refers to dodecylbenzenesulfonic acid, and colloidal silica contained in the polishing liquid had a particle size of 70 nm. The amount of each additive shown in Table 3 is mass % basis.

TABLE 3

| Ex. & | | | | | | Anti- | | | |
|---|---|---|---|---|---|---|---|---|---|
| Comp. | | | Amino | Oxidizing | | corrosion | | | |
| Ex. | Azole | Acid | acid | agent | Surfactant | agent | Alkali | Abrasive | pH |
| Ex. 4 | 18P | Oxalic | | Hydrogen | DBS | | ammonia | Colloidal | 9.1 |
| | 0.015 | acid | | peroxide | 0.05 | | | silica | |
| | | 0.5 | | 0.5 | | | | 0.5 | |
| Ex. 5 | Compound A | Oxalic | | Hydrogen | DBS | | ammonia | Colloidal | 9.1 |
| | 0.015 | acid | | peroxide | 0.05 | | | silica | |
| | | 0.5 | | 0.5 | | | | 0.5 | |
| Ex. 6 | Compound B | Oxalic | | Hydrogen | DBS | | ammonia | Colloidal | 9.1 |
| | 0.015 | acid | | peroxide | 0.05 | | | silica | |
| | | 0.5 | | 0.5 | | | | 0.5 | |
| Ex. 7 | Compound C | Oxalic | | Hydrogen | DBS | | ammonia | Colloidal | 9.1 |
| | 0.015 | acid | | peroxide | 0.05 | | | silica | |
| | | 0.5 | | 0.5 | | | | 0.5 | |
| Ex. 8 | Compound D | Oxalic | | Hydrogen | DBS | | ammonia | Colloidal | 9.1 |
| | 0.015 | acid | | peroxide | 0.05 | | | silica | |
| | | 0.5 | | 0.5 | | | | 0.5 | |
| Comp. | | Oxalic | | Hydrogen | DBS | | ammonia | Colloidal | 9.1 |
| Ex. 2 | | acid | | peroxide | 0.05 | | | silica | |
| | | 0.5 | | 0.5 | | | | 0.5 | |

Table 4 shows the polishing results. When the polishing liquid of Example 4 containing a vinylimidazole-vinylpyrrolidone copolymer was used, erosion was remarkably prevented to 5 nm, which is an excellent value, although dishing was 191 nm. In Examples 5 to 8, vinylimidazole homopolymers of varied molecular weights were incorporated into polishing liquids. Although polishing rate was not greatly changed, dishing prevention effect and erosion prevention effect were improved as increase in molecular weight of the polymer. In contrast, the polishing liquid of Comparative Example 2 containing no azole compound did not exhibit step covering performance and never prevented dishing and erosion. Thus, combination of the azole compound of the invention and a surfactant was found to enhance step reduction and effectively prevent dishing and erosion. Enhancement in erosion prevention effect is considered to be attributable to decrease in tantalum polishing rate.

TABLE 4

| | Polishing | Polishing | Polishing | | | | |
|---|---|---|---|---|---|---|---|
| Ex. & | rate, Cu | rate, Cu | rate, Ta | Step | | | |
| Comp. Ex. | (blanket) | (pattern) | (blanket) | reduction | Dishing | Erosion | Etching |
| Ex. 4 | 273 nm/min | 429 nm/min | 3 nm/min | AA | 191 nm | 5 nm | 0 nm/min |
| Ex. 5 | 347 nm/min | 475 nm/min | | AA | 176 nm | 7 nm | 0 nm/min |
| Ex. 6 | 327 nm/min | 483 nm/min | | AA | 167 nm | 19 nm | 0 nm/min |
| Ex. 7 | 354 nm/min | 480 nm/min | | AA | 144 nm | 13 nm | 0 nm/min |
| Ex. 8 | 337 nm/min | 488 nm/min | | AA | 128 nm | 7 nm | 0 nm/min |
| Comp. Ex. 2 | 312 nm/min | 433 nm/min | 32 nm/min | BB | 362 nm | 31 nm | 0 nm/min |

### Examples 9 to 11 and Comparative Example 3

Polishing liquids were prepared in a similar manner, but the amount of azole 18P was changed as shown in Table 5. The pH of each polishing liquid was adjusted by use of an alkali substance. The balance of each composition was water. The amount of each additive shown in Table 5 is mass% basis. A workpiece (cut wafer, 4×4 cm) was polished at a polishing pressure of 15 kPa. In Table 5, DBS refers to dodecylbenzenesulfonic acid, and colloidal silica contained in the polishing liquid had a particle size of 70 nm.

TABLE 5

| Ex. & | | | | | | Anti- | | | |
|---|---|---|---|---|---|---|---|---|---|
| Comp. | | | Amino | Oxidizing | | corrosion | | | |
| Ex. | Azole | Acid | acid | agent | Surfactant | agent | Alkali | Abrasive | pH |
| Ex. 9 | 18P | Oxalic | | Hydrogen | DBS | | ammonia | Colloidal | 9.1 |
| | 0.03 | acid | | peroxide | 0.05 | | | silica | |
| | | 1.0 | | 0.5 | | | | 1.0 | |
| Ex. | 18P | Oxalic | | Hydrogen | DBS | | ammonia | Colloidal | 9.1 |
| 10 | 0.05 | acid | | peroxide | 0.05 | | | silica | |
| | | 1.0 | | 0.5 | | | | 1.0 | |
| Ex. | 18P | Oxalic | | Hydrogen | DBS | | ammonia | Colloidal | 9.1 |
| 11 | 0.01 | acid | | peroxide | 0.05 | | | silica | |
| | | 1.0 | | 0.5 | | | | 1.0 | |
| Comp. | | Oxalic | | Hydrogen | DBS | | ammonia | Colloidal | 9.1 |
| Ex. 3 | | acid | | peroxide | 0.05 | | | silica | |
| | | 1.0 | | 0.5 | | | | 0.5 | |

The results are shown in Table 6. The rate of polishing tantalum barrier film decreased and erosion was more prevented, as increase in amount of azole P18. However, since addition of P18 in an excessive amount was prone to increase copper polishing rate, step reduction and dishing prevention effect tended to be impaired to degrees slightly higher than those of Comparative Example 3 employing no P18. Therefore, the amount of P18 is required to be appropriately modified to attain well balance in the composition.

TABLE 6

| | Polishing | Polishing | Polishing | | | | |
|---|---|---|---|---|---|---|---|
| Ex. & | rate, Cu | rate, Cu | rate, Ta | Step | | | |
| Comp. Ex. | (blanket) | (pattern) | (blanket) | reduction | Dishing | Erosion | Etching |
| Ex. 9 | 785 nm/min | 555 nm/min | 16 nm/min | AA | 380 nm | 10 nm | 0 nm/min |
| Ex. 10 | 805 nm/min | 766 nm/min | 10 nm/min | BB | 406 nm | 4 nm | 0 nm/min |
| Ex. 11 | 856 nm/min | 1,110 nm/min | 2 nm/min | BB | 455 nm | 0 nm | 0 nm/min |
| Comp. Ex. 3 | 809 nm/min | 700 nm/min | 41 nm/min | BB | 494 nm | 51 nm | 0 nm/min |

### Examples 12 to 17

An 8-inch wafer was polished at a polishing pressure of 15 kPa, and performance of the polishing compositions was evaluated.

The composition of the polishing compositions are shown in Table 7. Each composition contained the additives shown in Table 7, the balance being water. The amount of each additive shown in Table 7 is mass% basis. In Table 7, TTA refers to tolyltriazole, and Colloidal silica contained in the polishing composition had a particle size of 70 nm.

TABLE 7

| Ex. & | | | | | | Anti- | | | |
|---|---|---|---|---|---|---|---|---|---|
| Comp. | | | Amino | Oxidizing | | corrosion | | | |
| Ex. | Azole | Acid | acid | agent | Surfactant | agent | Alkali | Abrasive | pH |
| Ex. | 18P | Oxalic | | Hydrogen | DBS | | ammonia | Colloidal | 9.1 |
| 12 | 0.05 | acid | | peroxide | 0.07 | | | silica | |
| | | 0.5 | | 0.5 | | | | 0.5 | |
| Ex. | 18P | Oxalic | | Hydrogen | DBS | BTA | ammonia | Colloidal | 9.1 |
| 13 | 0.05 | acid | | peroxide | 0.07 | 0.01 | | silica | |
| | | 0.5 | | 0.5 | | | | 0.5 | |
| Ex. | 18P | Oxalic | | Hydrogen | DBS | BTA | ammonia | Colloidal | 9.1 |
| 14 | 0.05 | acid | | peroxide | 0.07 | 0.005 | | silica | |
| | | 0.5 | | 0.5 | | | | 0.5 | |
| Ex. | 18P | Oxalic | | Hydrogen | DBS | TTA | ammonia | Colloidal | 9.1 |
| 15 | 0.05 | acid | | peroxide | 0.07 | 0.005 | | silica | |
| | | 0.5 | | 0.5 | | | | 0.5 | |
| Ex. | 18P | Oxalic | | Hydrogen | DBS | TTA | ammonia | Colloidal | 9.1 |
| 16 | 0.05 | acid | | peroxide | 0.07 | 0.003 | | silica | |
| | | 0.5 | | 0.5 | | | | 0.5 | |
| Ex. | 18P | Oxalic | | Hydrogen | DBS | TTA | ammonia | Colloidal | 9.1 |
| 17 | 0.05 | acid | | peroxide | 0.07 | 0.003 | | silica | |
| | | 0.5 | | 0.5 | | quinaldinic | | 0.5 | |
| | | | | | | acid | | | |
| | | | | | | 0.1 | | | |

The results are shown Table 8. The Example 12 polishing composition contained an azole compound and a surfactant in combination, and the Example 13 polishing composition contained an azole compound, a surfactant, and an anti-corrosion agent in combination. The Example 13 polishing composition was found to more effectively prevent dishing, as compare with the Example 12 polishing composition. The Example 15 polishing composition contained TTA instead of BTA serving as an anti-corrosion agent exhibited improved dishing prevention performance, as compared with a polishing composition containing BTA as an anti-corrosion agent. Furthermore, use in combination of BTA and quinaldinic acid serving as anti-corrosion agents was found to enhance dishing prevention performance. Thus, the results indicate that use in combination of a surfactant and an anti-corrosion agent further enhances polishing performance of the polishing composition.

TABLE 8

| | Polishing | Polishing | Polishing | | | | |
|---|---|---|---|---|---|---|---|
| Ex. & | rate, Cu | rate, Cu | rate, Ta | Step | | | |
| Comp. Ex. | (blanket) | (pattern) | (blanket) | reduction | Dishing | Erosion | Etching |
| Ex. 12 | 570 nm/min | 640 nm/min | | AA | 215 nm | 0 nm | 0 nm/min |
| Ex. 13 | 24 nm/min | 503 nm/min | | AA | 161 nm | 9 nm | 0 nm/min |
| Ex. 14 | 169 nm/min | 524 nm/min | | AA | 160 nm | 8 nm | 0 nm/min |
| Ex. 15 | 32 nm/min | 535 nm/min | | AA | 92 nm | 21 nm | 0 nm/min |
| Ex. 16 | 267 nm/min | 511 nm/min | | AA | 161 nm | 5 nm | 0 nm/min |
| Ex. 17 | 195 nm/min | 534 nm/min | | AA | 115 nm | 20 nm | 0 nm/min |

### Examples 18 to 26

Polishing compositions were evaluated using an 8-inch wafer. The pressure was 15kPa. The pad was IC1400 (k group).

The compositions are shown in Table 9. The ingredient other than shown in the table was water. The added amounts are shown in the unit of % by mass. APS stands for ammonium persulfate, DBS dodecyl benzene sulfate, POE polyoxyethylene secondary alkyl ether phasphate, OLA oleic acid and BZI benzimidazol. Colloidal silica used had a particle size of 120 nm.

TABLE 9

| | | | | | Anti- | | | |
|---|---|---|---|---|---|---|---|---|
| Ex. | | | | | corrosion | | | |
| No. | Azole | Acid | Oxidizer | Surfactant | agent | Alkali | Abrasive | pH |
| 18 | Compound E | Oxalic | ASP | DBS 0.06% | BZI | ammonia | Colloidal | 9.1 |
| | 0.03% | acid | 1.5% | POE 0.01% | 0.003% | | silica | |
| | | 0.5% | | OLA 0.03% | | | 0.75% | |
| 19 | Compound F | Oxalic | ASP | DBS 0.06% | BZI | ammonia | Colloidal | 9.1 |
| | 0.05% | acid | 1.5% | POE 0.01% | 0.003% | | silica | |
| | | 0.5% | | OLA 0.03% | | | 0.75% | |
| 20 | Compound G | Oxalic | ASP | DBS 0.06% | BZI | ammonia | Colloidal | 9.1 |
| | 0.05% | acid | 1.5% | POE 0.01% | 0.003% | | silica | |
| | | 0.5% | | OLA 0.03% | | | 0.75% | |
| 21 | Compound H | Oxalic | ASP | DBS 0.06% | BZI | ammonia | Colloidal | 9.1 |
| | 0.05% | acid | 1.5% | POE 0.01% | 0.003% | | silica | |
| | | 0.5% | | OLA 0.03% | | | 0.75% | |
| 22 | Compound | Oxalic | ASP | DBS 0.07% | BZI | ammonia | Colloidal | 9.1 |
| | 72W | acid | 1.5% | POE 0.03% | 0.005% | | silica | |
| | 0.05% | 0.5% | | OLA 0.03% | | | 0.75% | |
| 23 | Compound I | Oxalic | ASP | DBS 0.07% | BZI | Ethylene | Colloidal | 9.1 |
| | 0.05% | acid | 1.5% | POE 0.01% | 0.003% | diamine | silica | |
| | | 0.5% | | OLA 0.03% | | 0.01% + ammonia | 0.75% | |
| 24 | Compound J | Oxalic | ASP | DBS 0.07% | BZI | ammonia | Colloidal | 9.1 |
| | 0.05% | acid | 1.5% | POE 0.01% | 0.003% | | silica | |
| | | 0.5% | | OLA 0.03% | | | 1.0% | |
| 25 | Compound K | Oxalic | ASP | DBS 0.07% | BZI | ammonia | Colloidal | 9.1 |
| | 0.05% | acid | 1.5% | POE 0.01% | 0.003% | | silica | |
| | | 0.5% | | OLA 0.03% | | | 1.2% | |
| 26 | Compound L | Oxalic | ASP | DBS 0.07% | BZI | ammonia | Colloidal | 9.0 |
| | 0.05% | acid | 1.5% | POE 0.01% | 0.003% | | silica | |
| | | 0.5% | | OLA 0.03% | | | 1.55% | |

The results are shown in Table 10.

In Examples 18-21, various vinyl imodazol and 1-vinyl pyrrolidone copolymers were used as the azoles. In any of Examples 18-21, the dishing and the erosion were low. In particular, when compounds with azole moieties having a high molecular weight were used, a high dishing performance was obtained (see Example 22) and a same performance was obtained by addition at a small amount of the azole moieties-containing compound in Example 18.

In Example 23, a small amount of ethylene diamine was added as the alkali and polishing was conducted. The dishing was slightly enlarged. As a dishing may be required to some extent depending on the process, addition of ethylene diamine is useful in such a case.

In Examples 24-26, the amount of added colloidal silica was varied. The dishing tends to slightly increase as the amount of added colloidal silica increases, but the increase is low.

TABLE 10

| | | Cu (pattern) | | |
|---|---|---|---|---|
| Example | Cu (blanket) | polishing | | |
| No. | polishing rate | rate | Dishing | Erosion |
| 18 | 510 nm/min | 585 nm/min | 12 nm | 10 nm |
| 19 | 511 nm/min | 588 nm/min | 22 nm | 7 nm |
| 20 | 506 nm/min | 614 nm/min | 3 nm | 10 nm |
| 21 | 489 nm/min | 602 nm/min | 8 nm | 18 nm |
| 22 | 512 nm/min | 679 nm/min | 8 nm | 6 nm |
| 23 | 419 nm/min | 584 nm/min | 37 nm | 7 nm |
| 24 | 612 nm/min | 731 nm/min | 56 nm | 6 nm |
| 25 | 606 nm/min | 736 nm/min | 71 nm | 5 nm |
| 26 | 587 nm/min | 729 nm/min | 82 nm | 8 nm |

### Examples 27 to 31 and Comparative Examples 4 to 8

Acid, oxidizing agent, surfactant, anti-corrosion agent, azole and abrasive were added as shown in Table 11 and the pH was adjusted with an alkali. The ingredient not shown in Table 11 was water. The added amounts are shown in the unit of mass %. The wafer used had a cut size of 4×4 cm.

DBS stands for dodecyl benzene sulphate, BTA benzotriazole, and THFA tetrahydrofrufryl amine. THe colloidal silica used has a particle size of 70-80 nm.

TABLE 11

| | | | | | Anti- | | | |
|---|---|---|---|---|---|---|---|---|
| Ex. | | Oxidizing | | | corrosion | | | |
| Com. Ex. | Acid | agent | Surfactant | Azole | agent | Alkali | Abrasive | pH |
| Com. Ex. 4 | Lactic | H₂O₂ 2.0% | DBS 0.050% | | BTA | ammonia | Colloidal | 8.7 |
| | acid | | | | 0.010% | 0.35% | silica | |
| | 1.5% | | | | | THFA 0.3% | 1.0% | |
| Com. Ex. 5 | Lactic | H₂O₂ 2.0% | DBS 0.025% | | BTA | ammonia | Colloidal | 8.8 |
| | acid | | | | 0.010% | 0.35% | silica | |
| | 1.5% | | | | | THFA 0.3% | 1.0% | |
| Com. Ex. 6 | Lactic | H₂O₂ 2.0% | DBS 0.050% | | BTA | ammonia | Colloidal | 9.3 |
| | acid | | | | 0.010% | 0.35% | silica | |
| | 1.0% | | | | | THFA 0.3% | 1.0% | |
| Com. Ex. 7 | Oxalic | H₂O₂ 2.0% | DBS 0.050% | | BTA | ammonia | Colloidal | 9.1 |
| | acid | | | | 0.010% | 0.35% | silica | |
| | 0.5% | | | | | THFA 0.3% | 1.0% | |
| Com. Ex. 8 | Lactic | H₂O₂ 2.0% | | | BTA | ammonia | Colloidal | 8.9 |
| | acid | | | | 0.010% | 0.35% | silica | |
| | 1.5% | | | | | THFA 0.3% | 1.0% | |
| Ex. 27 | Oxalic | H₂O₂ 0.5% | DBS 0.050% | P18 | BTA | ammonia | Colloidal | 9.0 |
| | acid | | | 0.050% | 0.005% | 0.27% | silica | |
| | 0.5% | | | | | | 1.0% | |
| Ex. 28 | Oxalic | H₂O₂ 0.5% | DBS 0.050% | P18 | BTA | ammonia | Colloidal | 9.0 |
| | acid | | | 0.050% | 0.010% | 0.27% | silica | |
| | 0.5% | | | | | | 1.0% | |
| Ex. 29 | Oxalic | H₂O₂ 0.5% | DBS 0.050% | P18 | BTA | ammonia | Colloidal | 9.0 |
| | acid | | | 0.050% | 0.015% | 0.27% | silica | |
| | 0.5% | | | | | | 1.0% | |
| Ex. 30 | Oxalic | H₂O₂ 0.5% | DBS 0.050% | P18 | BTA | ammonia | Colloidal | 9.0 |
| | acid | | | 0.030% | 0.015% | 0.27% | silica | |
| | 0.5% | | | | | | 0.5% | |
| Ex. 31 | Oxalic | H₂O₂ 0.5% | DBS 0.050% | P18 | BTA | ammonia | Colloidal | 9.0 |
| | acid | | Lauryl | 0.050% | 0.010% | 0.27% | silica | |
| | 0.5% | | phophate | | | | 0.5% | |
| | | | 0.001% | | | | | |

The polishing pressure and the results are shown in Table 12. P_{RR}/B_{RR} stands for a ratio between a polishing rate (P_{RR}) for a copper-pattern wafer and a polishing rate (B_{RR}) for a copper-blanket wafer.

In Comparative Examples 4-8, where a compound having three or more azole moieties was not added, the step reduction is low and, in all of these, P_{RR}/B_{RR} was low. In Examples 27-31 where a compound having three or more azole moieties was added, step reduction was significantly improved. Particularly in Examples 28-31, P_{RR}/B_{RR} increased and the step reduction was improved, in comparison with Comparative Examples. Further, in Examples 30 and 31, almost no polishing was taken place after the remaining copper film thickness became about 300 nm. The 100 μm/100 μm step completely disappeared and no step was observed in other patterns. It was confirmed that a slurry with a large P_{RR}/B_{RR} is significantly excellent in the step reduction performance.

TABLE 12

| | | Cu (blanket) | Cu (pattern) | | |
|---|---|---|---|---|---|
| | | polishing | polishing | | |
| Ex. | Polishing | rate | rate | P_{RR}/ | Step |
| Com. Ex. | Pressure | B_{RR} | P_{RR} | B_{RR} | reduction |
| Com. Ex. 4 | 30 kPa | 50 nm/min | 170 nm/min | 3.40 | BB |
| Com. Ex. 5 | 30 kPa | 450 nm/min | 590 nm/min | 1.31 | BB to CC |
| Com. Ex. 6 | 30 kPa | 40 nm/min | 130 nm/min | 3.25 | BB |
| Com. Ex. 7 | 30 kPa | 400 nm/min | 520 nm/min | 1.30 | BB |
| Com. Ex. 8 | 30 kPa | 510 nm/min | 590 nm/min | 1.15 | BB to CC |
| Ex. 27 | 15 kPa | 430 nm/min | 435 nm/min | 1.01 | AA |
| Ex. 28 | 15 kPa | 70 nm/min | 440 nm/min | 6.29 | AA |
| Ex. 29 | 15 kPa | 40 nm/min | 380 nm/min | 9.50 | AA |
| Ex. 30 | 15 kPa | 60 nm/min | 305 nm/min | 5.08 | AA |
| Ex. 31 | 15 kPa | 60 nm/min | 360 nm/min | 6.00 | AA |

### Examples 32 to 34

Acid, oxidizing agent, surfactant, anti-corrosion agent, azole and abrasive were added as shown in Table 13 and the pH was adjusted with an alkali. The ingredient not shown in Table 13 was water. The added amounts are shown by mass%. The wafer used was an 8-inch wafer (Sematic 854 corresponding product).

DBS stands for dodecyl benzene sulphate, and BTA benzotriazole. The colloidal silica used has a particle size of 10-80 nm.

TABLE 13

| | | | | | Anti- | | | |
|---|---|---|---|---|---|---|---|---|
| | | Oxidizing | | | corrosion | | | |
| Ex. | Acid | agent | Surfactant | Azole | agent | Alkali | Abrasive | pH |
| Ex. 32-34 | Oxalic | H₂O₂ | DBS | 18P | — | ammonia | Colloidal | 9.3 |
| | acid | 0.5% | 0.070% | 0.050% | | 0.33% | silica | |
| | 0.5% | | POE | | | | 0.5% | |
| | | | 0.030% | | | | | |

The polishing pressure and polishing results are shown in Table 14. The evaluation of the dishing was conducted by considering, as the basis, a polishing rate when a pattern wafer is polished until the thickness of a copper layer becomes about 300 nm; overpolising the copper layer by 50% based on the initial copper layer thickness; and taking the height of the resultant 100 μm/100 μm step as the dishing.

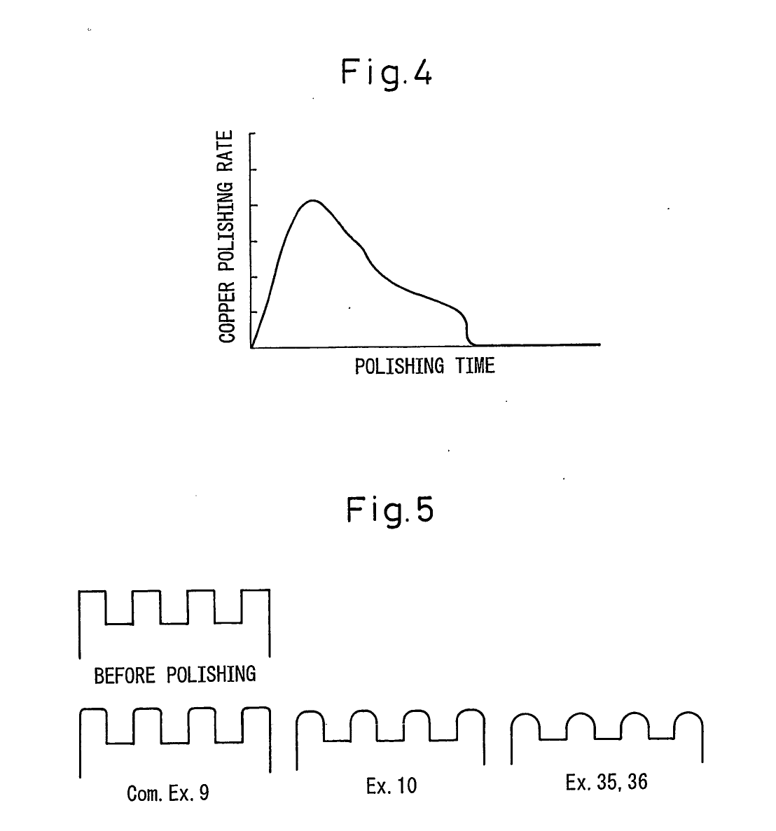

In Examples 32 to 34, DBS as well as POE were added as the surfactant and no anti-corrosion agent was added. The step reduction was significantly high and it is considered that this is because P_{RR}/B_{RR} was high. The dishing at 100 μm/100 μm step was small, 50-60 nm. With a slurry having a high P_{RR}/B_{RR} of the present invention, as shown in FIG. 4, the polishing rate is high at a stage where there is a step and, while the step is decreasing, the polishing rate is decreasing to B_{RR}. Therefore, it is considered that as the step reduction is enhanced, when a barrier film has appeared, the polishing rate becomes small so that the dishing becomes small.

It is clear from the results of Examples 32-34 that, since the polishing rate, step reduction and dishing were not influenced by change in the polishing pressure, these do not depend on the polishing pressure.

TABLE 14

| Ex. | Polishing | | | | Step | |
|---|---|---|---|---|---|---|
| Com. Ex. | Pressure | B_{RR} | P_{RR} | P_{RR}/B_{RR} | reduction | Dishing |
| Ex. 32 | 14 kPa | 130 nm/min | 550 nm/min | 4.23 | AA | 50-60 nm |
| Ex. 33 | 10 kPa | 110 nm/min | 450 nm/min | 4.09 | AA | 40-60 nm |
| Ex. 34 | 20 kPa | 140 nm/min | 630 nm/min | 4.50 | AA | 70-80 nm |

### Examples 35-36 and Comparative Examples 9-10

A 4 cm×4 cm pattern wafer was polished by a depth of about 300 nm using the compositions of Examples 31 and 27 and Comparative Examples 8 and 6. The 100 μm/100 μm step was measured by a contact-type step measuring device. The corners of protrusion were observed. The results are shown in Table 15 and FIG. 5.

In Comparative Example 9, the corners of protrusions were slightly rounded. In Comparative Example 10, where a surfactant was added, the corners of protrusions were rounded and became smooth. In Examples 35 and 36 where a compound having three or more azole moieties was added, the corners were rounded more than in Comparative Examples 9 and 10. It is considered that these results relate to a fact that P_{RR}/B_{RR} was high and the step reduction was high, and corner portions were preferentially polished to increase P_{RR} and the polishing rate, B_{RR}, decreased as corners did not exist.

TABLE 15

| Ex. | | Polishing | |
|---|---|---|---|
| Com. Ex. | Composition | pressure | Corner appearance |
| Ex. 35 | Ex. 31 | 20 kPa | Corners rounded more |
| | | | than Com. Ex. 9 and 10 |
| Ex. 36 | Ex. 27 | 20 kPa | Corners rounded more |
| | | | than Com. Ex. 9 and 10 |
| Com. Ex. 9 | Com. Ex. 8 | 20 kPa | Corners slightly |
| | | | rounded |
| Com. Ex. 10 | Com. Ex. 6 | 20 kPa | Significantly rounded |
| | | | and smooth corners |

### INDUSTRIAL APPLICABILITY

In accordance with the present invention, the compound having three or more azole moieties enables to reduce dishing of metallic film, inter alia, copper film during polishing thereof. In addition, the compound having three or more azole moiety enables to regulate polishing rate for the barrier film, thereby preventing erosion. Among these compounds having three or more azole moieties, vinylimidazole polymer more effectively reduces dishing by use in combination with an anti-corrosion agent and a surfactant.

Through employment of the polishing method of the present invention by use of the polishing composition containing a compound having three or more azole moieties and employment of the method of the present invention for producing a substrate, a substrate having a remarkably flat surface can be readily produced.

1. A polishing composition, comprising (A) a compound having three or more azole moieties, (B) an oxidizing agent, and (C) one or more species selected from among an amino acid, an organic acid, and an inorganic acid.

2. The polishing composition according to claim 1, wherein the compound having three or more azole moieties (A) is a polymer of an azole having a vinyl group.

3. The polishing composition according to claim 1, wherein the compound having three or more azole moieties (A) is soluble in water.

4. The polishing composition according to claim 1, wherein the compound having three or more azole moieties (A) has a mass average molecular mass in a range of 300 to 5,000,000.

5. The polishing composition according to claim 1, wherein the content of the compound having three or more azole moieties (A) is in a range of 0.001 to 1 mass %.

6. The polishing composition according to claim 1, wherein amino acid comprises at least one species selected from the group consisting of glycine, L-alanine, β-alanine, L-2-aminobutyric acid, L-norvaline, L-valine, L-leucine, L-norleucine, L-isoleucine, L-allo-isoleucine, L-phenylalanine, L-proline, sarcosine, L-omithine, L-lysine, taurine, L-serine, L-threonine, L-allo-threonine, L-homoserine, L-tyrosine, 3,5-diiodo-L-tyrosine, β-(3,4-dihydroxyphenyl)-L-alanine, L-thyroxine, 4-hydroxy-L-proline, L-cysteine, L-methionine, L-ethionine, L-lanthionine, L-cystathionine, L-cystine, L-cysteic acid, L-aspartic acid, L-glutamic acid, S-(carboxymethyl)-L-cysteine, 4-aminobutyric acid, L-asparagine, L-glutamine, azaserine, L-arginine, L-canavanine, L-citrulline, δ-hydroxy-L-lysine, creatine, L-kynurenine, L-histidine, 1-methyl-L-histidine, 3-methyl-L-histidine, ergothioneine, and L-tryptophan.

7. The polishing composition as described in claim 1, wherein the organic acid comprises at least one species selected from the group consisting of formic acid, acetic acid, propionic acid, butyric acid, valeric acid, 2-methylburyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid.

8. The polishing composition according to claim 1, wherein the inorganic acid is sulfuric acid, nitric acid, phosphoric acid, or a salt thereof.

9. The polishing composition according to claim 1, wherein the content of the one or more species selected form the group consisting of an amino acid, an organic acid and an inorganic acid (C) is in a range of 0.001 to 10 mass %.

10. The polishing composition according to claim 1, wherein the oxidizing agent comprises at least one species selected from the group consisiting of oxygen, ozone, hydrogen peroxide, alkyl peroxides, peracids, permanganate salts, periodate salts, persulfate salts, polyoxo acids, and hypochlorite salts.

11. The polishing composition according to claim 1, wherein the content of the oxidizing agent (B) is in a range of 0.01 to 30 mass %.

12. The polishing composition according to claim 1, which further contains a surfactant.

13. The polishing composition according to claim 12, wherein the surfactant comprises at least one species selected from the group consisting of anionic surfactants, cationic surfactants, nonionic surfactants, and ampholytic surfactants.

14. The polishing composition according to claim 12, wherein the surfactant is at least one species selected from the group consisting of an alkylaromatic-sulfonic acid or a salt thereof, polyoxyethylene alkyl phosphoric acid or a salt thereof, alkyl phophoric acid or a salt thereof, and a fatty acid or a salt thereof.

15. The polishing composition according to claim 1, wherein the content of the surfactant is in a range of 5 mass % or less.

16. The polishing composition according to claim 1, which further contains a protective-film-forming agent.

17. The polishing composition according to claim 16, wherein the content of the protective-film-forming agent is in a range of 5 mass % or less.

18. The polishing composition according to claim 1, wherein the protective-film-forming agent comprises at least one species selected from the group consisting of benzotriazole, tolyltriazole, hydroxybenzotriazole, carboxybenzotriazole, benzimidazole, tetrazole, and quinaldinic acid.

19. The polishing composition according to claim 1, wherein the content of the protective-film-forming agent is in a range of 10 mass % or less.

20. The polishing composition according to claim 1, which further contains an alkali substance.

21. The polishing composition according to claim 20, wherein the alkali substance comprises at least one species selected from the group consisting of ammonia, amines, polyamines, alkali metal compounds, and alkaline earth metal compounds.

22. The polishing composition according to claim 20, wherein the content of the alkali substance is in a range of 10 mass % or less.

23. The polishing composition according to claim 1, which further comprises an abrasive.

24. The polishing composition according to claim 23, wherein the abrasive comprises at least one species selected from the group consisting of silica, alumina, ceria, titania, and organic abrasive.

25. The polishing composition according to claim 23, wherein the content of the abrasive is in a range of 30 mass % or less.

26. The polishing composition according to claim 1, which has a pH of 5 to 11.

27. The polishing composition according to claim 1, which is used for polishing a metal film provided on a substrate having trenches such that the metal film fills the trenches.

28. The polishing composition according to claim 1, wherein a ratio (P_{RR}/B_{RR}), between a metal film polishing rate (P_{RR}) for polishing a metal film formed on a substrate having trenches such that the metal film fills the trenches, or polishing a metal film formed on a substrate having trenches and a barrier metal film formed on the substrate such that the metal film fills the trenches, and a metal film polishing rate (B_{RR}) for polishing a flat blanket metal film, is 3.5 or more.

29. A composition which forms the polishing composition as set forth in claim 5, by dilution.

30. A kit comprising a plurality of compositions, which forms the polishing composition as set forth in claim 1 by mixing or by mixing and dilution.

31. A polishing method comprising forming a metal film provided on the substrate having trenches such that the metal film fills the trenches, by use of the polishing composition as set forth in claim 1.

32. A polishing method comprising forming a barrier metal film on a substrate having trenches, and polishing, by use of the polishing composition as recited in claim 1, a metal film provided on the substrate such that the metal film fills the trenches.

33. A polishing method comprising a metal film, wherein a metal film formed on a substrate having trenches such that the metal film fills the trenches, or a metal film formed on a substrate having trenches and a barrier metal film formed on the substrate such that the metal film fills the trenches, has protrusions, and corners of the protrusions are preferentially polished by the composition as set forth in claim 1.

34. The polishing method according to claim 33, wherein the metal film comprises copper, a copper-containing alloy, iron, or an iron-containing alloy.

35. The polishing method according to claim 33, wherein the barrier metal film comprises tantalum-containing metal such as tantalum or tantalum nitride.

36. The method for polishing a substrate, the method comprising planarizing, by use of the polishing composition as recited in claim 1, a metal film provided on a substrate having trenches such that the metal film fills the trenches.

37. The method for producing a substrate, the method comprising a step of polishing, through the polishing method as recited in claim 31, a metal film provided on a substrate having trenches such that the metal film fills the trenches.

38. A method for using the composition as set forth in claim 29 as a transportation or storage composition.

39. A method for using the composition as set forth in claim 30 for transportation or storage compositions.

40. The method for producing a substrate, the method comprising a step of polishing, through the polishing method as recited in claim 32, a metal film provided on a substrate having trenches such that the metal film fills the trenches.

41. A method for using the composition as set forth in claim 37 as a transportation or storage composition.

42. A method for using the composition as set forth in claim 38 for transportation or storage compositions.

43. The method for producing a substrate, the method comprising a step of polishing, through the polishing method as recited in claim 33, a metal film provided on a substrate having trenches such that the metal film fills the trenches.

44. A method for using the composition as set forth in claim 33 as a transportation or storage composition.

45. A method for using the composition as set forth in claim 44 for transportation or storage compositions.
